(19) United States
(12) Patent Application Publication
(10) Pub. No.: US 2015/0380526 A1
(43) Pub. Date: Dec. 31, 2015

(54) METHODS FOR FORMING FIN STRUCTURES WITH DESIRED DIMENSIONS FOR 3D STRUCTURE SEMICONDUCTOR APPLICATIONS

(71) Applicant: Applied Materials, Inc., Santa Clara, CA (US)

(72) Inventors: Ludovic GODET, Sunnyvale, CA (US); Srinivas D. NEMANI, Sunnyvale, CA (US); Jun XUE, San Jose, CA (US); Ellie Y. YIEH, San Jose, CA (US)

(21) Appl. No.: 14/469,241

(22) Filed: Aug. 26, 2014

Related U.S. Application Data
(60) Provisional application No. 62/018,018, filed on Jun. 27, 2014.

(51) Int. Cl. H01L 29/66; H01L 21/265; H01L 21/3205

(52) U.S. Cl. CPC H01L 29/66795; H01L 21/3205; H01L 21/26506

(57) ABSTRACT

Methods for forming fin structure with desired materials formed on different locations of the fin structure using an ion implantation process to define an etching stop layer followed by an etching process for manufacturing three dimensional (3D) stacking of fin field effect transistor (FinFET) for semiconductor chips are provided. In one embodiment, a method for forming a structure on a substrate includes performing an ion implantation process on a substrate having a plurality of structures formed thereon, forming an ion treated region in the structure at an interface between the ion treated region and an untreated region in the structure defining an etch stop layer, and performing a remote plasma etching process to etch the treated region from the substrate to exposed the untreated region.

### CROSS-REFERENCE TO RELATED APPLICATIONS

This application claims benefit of U.S. Provisional Patent Application Ser. No. 62/180,180, filed Jun. 27, 2014, which is incorporated by reference in its entirety.

### BACKGROUND

1. Field

Embodiments generally relate to methods for forming three dimension structures with desired materials and dimensions on a semiconductor substrate. More specifically, embodiments relate to methods for forming three dimension structures on a semiconductor substrate with desired and uniform dimensions of the structure across the substrate by an ion implantation process to form an etching stop layer along with a selective etching process for fin field effect transistor (FinFET) semiconductor manufacturing applications.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI technology have placed additional demands on processing capabilities. Reliable formation of gate structures on the substrate is important to VLSI and ULSI success and to the continued effort to increase circuit density and quality of individual substrates and die.

As circuit densities increase for next generation devices, the widths of interconnects, such as vias, trenches, contacts, gate structures and other features, as well as the dielectric materials therebetween, decrease to 45 nm and 32 nm dimensions, whereas the thickness of the dielectric layers remain substantially constant, with the result of increasing the aspect ratios of the features. In order to enable the fabrication of next generation devices and structures, three dimensional (3D) stacking of features in semiconductor chips is often utilized. In particular, fin field effect transistors (FinFET) are often utilized to form three dimensional (3D) structures in semiconductor chips. By arranging transistors in three dimensions instead of conventional two dimensions, multiple transistors may be placed in the integrated circuits (ICs) very close to each other. Recently, complementary metal oxide semiconductor (CMOS) FinFET devices have been widely used in many logic and other applications and are integrated into various different types of semiconductor devices. FinFET devices typically include semiconductor fins with high aspect ratios in which the channel and source/drain regions for the transistor are formed thereover. A gate electrode is then formed over and along side of a portion of the fin utilizing the advantage of the increased surface area of the channel and source/drain regions to produce faster, more reliable and better-controlled semiconductor transistor devices. Further advantages of FinFETs include reduced short channel effect and higher current flow.

FIG. 1A depicts an exemplary embodiment of a fin field effect transistor (FinFET) 150 disposed on a substrate 100. The substrate 100 may be a silicon substrate, a germanium substrate, or a substrate formed from other semiconductor materials. In one embodiment, the substrate 100 may include p-type or n-type dopants doped therein. The substrate 100 includes a plurality of semiconductor fins 102 formed thereon isolated by shallow trench isolation (STI) structures 104. The shallow trench isolation (STI) structures 104 may be formed by an insulating material, such as a silicon oxide material, a silicon nitride material or a silicon carbon nitride material.

The substrate 100 may include a portion in NMOS device region 101 and a portion in PMOS device region 103 as needed, and each of the semiconductor fins 102 may be sequentially and alternatively formed in the NMOS device region 101 and the PMOS device region 103 in the substrate 100. The semiconductor fins 102 are formed protruding above the top surfaces of the shallow trench isolation (STI) structures 104. Subsequently, a gate structure 106, typically including a gate electrode layer disposed on a gate dielectric layer, is deposited on both of the NMOS device region 101 and the PMOS device region 103 and over the semiconductor fins 102.

The gate structure 106 may be patterned to expose portions 148, 168 of the semiconductor fins 102 uncovered by the gate structure 106. The exposed portions 148, 168 of the semiconductor fins 102 may then be doped with dopants to form lightly doped source and drain (LDD) regions using an implantation process.

FIG. 1B depicts a cross sectional view of the substrate 100 including the plurality of semiconductor fins 102 formed on the substrate 100 isolated by the shallow trench isolation (STI) structures 104. The plurality semiconductor fins 102 formed on the substrate 100 may be part of the substrate 100 extending upwards from the substrate 100 utilizing the shallow trench isolation (STI) structures 104 to isolate each of the semiconductor fins 102. In another embodiment, the semiconductor fins 102 may be individually formed structures disposed on the substrate 100 that are made from materials different than the substrate 100 using suitable techniques available in the art. The semiconductor fins 102 may have different surfaces 120, including a first sidewall 120a and a second side wall 120b connected by a top surface 120c, each fabricated from different materials.

During manufacturing of the fin structures 120, different densities of the fin structures 120 may result in different etching rates or chemical mechanical polishing (CMP) rates. One of the problems associated with the pattern density with small dimension features is the occurrence of a microloading effect, which is a measure of the variation in feature dimensions between regions of high and low feature density. During a CMP process, the low feature density regions (e.g., isolated regions) often have higher polishing rates compared to the high feature density regions (e.g., dense regions) due to larger total exposed surface area in the dense regions, thereby resulting in a higher polishing rate in the low density regions. Thus, due to different polishing rates in high and low feature density regions, it is often observed that the fin structures 250 may have different dimensions, such as a first height 198 of the fin structure that is greater than a second height 199 of the fin structure as measured from a surface 110 of the shallow trench isolation (STI) structures 104. In many cases, the non-uniform resultant heights and dimensions of the fin structures 120 often result in profile deformation and structure collapse after subsequently processing. Deformed features formed in the fin structure 250 often results in an inability to hold critical dimension features later formed on the fin structure and poor patterned transfer.

Thus, there is a need for improved methods for forming fin structures with uniform and desired dimension suitable for three dimensional (3D) stacking of semiconductor chips or other semiconductor devices.

### SUMMARY

Methods for forming fin structures with desired materials, profile and dimensions for three dimensional (3D) stacking of fin field effect transistor (FinFET) for semiconductor chips are provided. The methods utilize an ion implantation process to implant ions into the fin structure forming an etching stop layer to promote etching selectivity. In one embodiment, a method for forming a structure on a substrate includes performing an ion implantation process on a substrate having a plurality of structures formed thereon, forming an ion treated region in the structure at an interface between the ion treated region and an untreated region in the structure defining an etch stop layer, and performing a remote plasma etching process to etch the treated region from the substrate to exposed the untreated region.

In another embodiment, a method for forming a structure on a substrate includes forming an etching stop layer in a structure disposed on a substrate by an ion implantation process, performing a remote plasma etching process to etch the structure until reaching the etching stop layer, defining openings exposing of the etching stop layer of the structure, and performing a selective deposition process to form a material layer in the openings and on the etching stop layer.

In yet another embodiment, a method for forming a structure on a substrate includes performing a directional ion plasma process on a structure formed on a substrate to form an etching stop layer in the structure, wherein the structure is formed on the substrate between shallow trench isolation structures fabricated from insulating materials, performing a remote plasma etching process including hydrogen radicals to etch a portion of the structure until reaching the etching stop layer exposing an underlying portion of the structure, and performing a selective deposition process to form a material layer on the underlying portion of the structure.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a schematic perspective view of a substrate having a fin field effect transistor (FinFET) structure formed thereon in a conventional manner;

FIG. 1B depicts a cross sectional view of a substrate having a portion of the fin field effect transistor (FinFET) structure formed thereon in a conventional manner;

FIG. 2A depicts an apparatus which may be utilized to dope dopants in a structure on a substrate;

FIG. 2B depicts another embodiment of an apparatus which may be utilized to dope dopants in a structure on a substrate;

FIG. 3 depicts another embodiment of an apparatus which may be utilized to dope dopants in a structure on a substrate;

FIG. 4 depicts another embodiment of an apparatus which may be utilized to dope dopants in a structure on a substrate;

FIG. 5 depict an apparatus that may be utilized to perform an selective etching process;

FIG. 6 depicts a flow diagram of a method for forming fin structures with uniform structure profile on a substrate; and

FIG. 7A-7D depict one embodiment of a sequence for forming form fin structures with uniform structure profile during a manufacturing process, for example, such as the process depicted in FIG. 6.

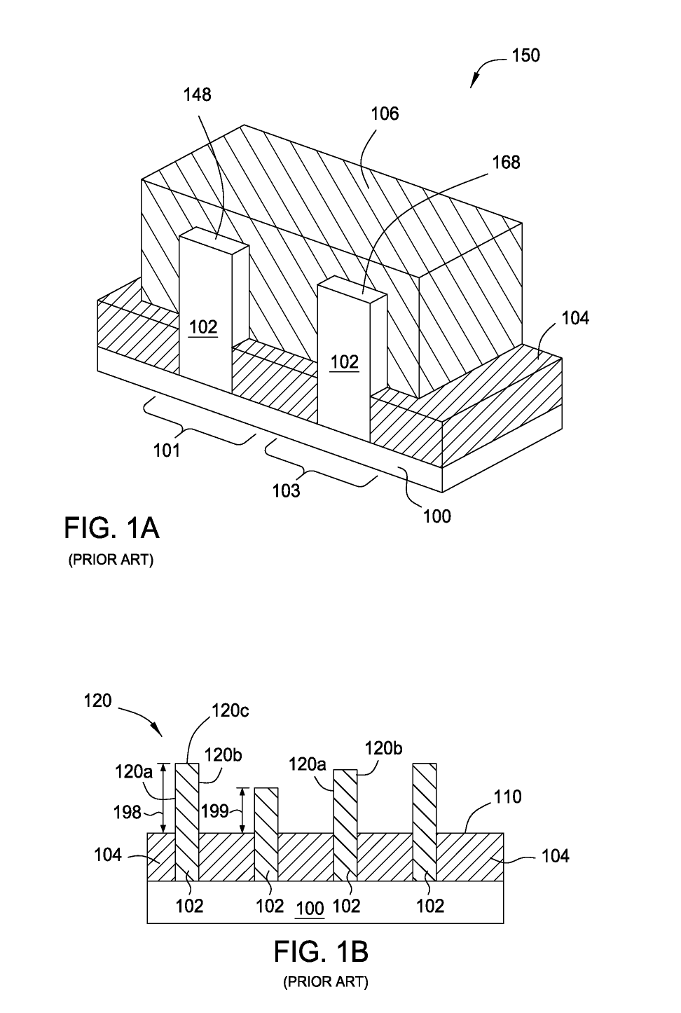

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods for forming structures with desired materials, profile and dimensions for three dimensional (3D) stacking of fin field effect transistor (FinFET) for semiconductor chips are provided. The methods utilize an ion implantation process to implant ions into a fin structure forming an etching stop layer to promote etching selectivity. The structure may include a fin structure, a gate structure, a contact structure, or any suitable structure in semiconductor devices, particularly for three dimensional (3D) stacking of fin field effect transistor (FinFET) semiconductor structures. In one embodiment, the ion implantation process is performed to implant dopants into the structure, forming an etching stop interface in the structures. Subsequently, an etching process may be performed to selectively etch the areas with dopants doped therein, without attacking the areas without dopants. An additional material may be later formed on the etched interface to form the structure with composite material having a desired dimension and profile.

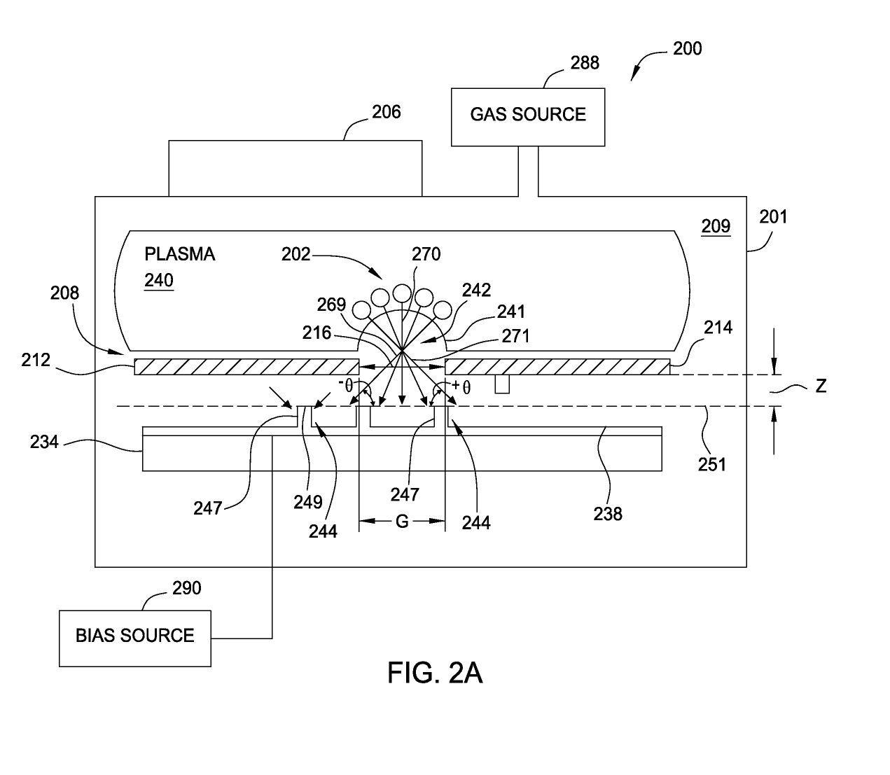

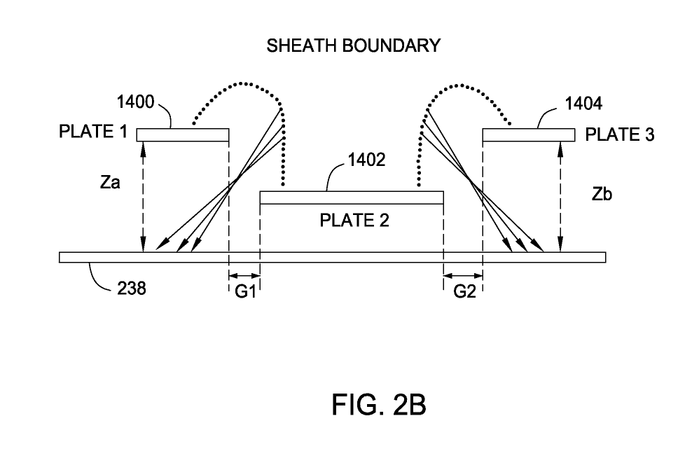

FIG. 2A is a sectional view of one embodiment of a processing chamber 200 suitable for doping dopants into a substrate. Suitable processing chambers that may be adapted for use with the teachings disclosed herein include, for example, a processing chamber available from Applied Materials, Inc. of Santa Clara, Calif. Although the processing chamber 200 is shown having a plurality of features that enable ion doping performance, it is contemplated that other processing chambers from other manufactures may also be adapted to benefit from one or more of the inventive features disclosed herein. The processing chamber 200 as described herein may be utilized as a plasma doping apparatus. However, the processing chamber 200 may also include, but not be limited to, etching and deposition systems. Furthermore, the plasma doping apparatus can perform many differing material modification processes on a substrate. One such process includes doping a substrate, such as a semiconductor substrate, with desired dopants.

The processing chamber 200 may include chamber body 201 defining an interior processing region 209. A substrate support 234 is disposed in the processing chamber 200. A substrate 238 having features 244 formed thereon may be disposed on the substrate support 234 during a directional plasma process. The substrate 238 may include, but not be limited to, a semiconductor wafer, flat panel, solar panel, and polymer substrate. The semiconductor wafer may have a disk shape with a diameter of 200 millimeters (mm), 300 millimeters (mm) or 450 millimeters (mm) or other size, as needed.

A RF plasma source 206 is coupled to the chamber body 201 and configured to generate a plasma 240 in the processing chamber 200. In the embodiment of FIG. 2A, a plasma sheath modifier 208 is disposed in the interior processing region 209. The plasma sheath modifier 208 includes a pair of modifier 212, 214 defining a gap 216 therebetween. The gap 216 defines a horizontal spacing (G). In some embodiments, the plasma sheath modifier 208 may include an insulator, conductor or semiconductor. The pair of modifiers 212, 214 may be a pair of sheets having a thin, flat shape. In other embodiments, the pair of modifiers 212, 214 may be other shapes such as tube shaped, wedge shaped, and/or have a beveled edge proximate the gap 316. In one embodiment, the modifiers 212, 214 may be fabricated of quartz, alumina, boron nitride, glass, polysilicon, silicon nitride, silicon carbide, graphite and the like.

In one embodiment, the horizontal spacing of the gap 216 defined by the pair of modifiers 212, 214 may be about 6.0 millimeters (mm). The pair of modifiers 212, 214 may also be positioned to define a vertical spacing (Z) above a plane 251. The plane 251 is defined by a front surface of the substrate 238 or a surface of the substrate support 234. In one embodiment, the vertical spacing (Z) may be about 3.0 mm.

A gas source 288 is coupled to the processing chamber 200 to supply an ionizable gas to the interior processing region 209. Examples of an ionizable gas include, but are not limited to, BF₃, BI₃N₂, Ar, PH₃, AsH₃, B₂H₆, H₂, Xe, Kr, Ne, He, SiH₄, SiF₄, SF₆, C₂F₆, CHF₃, GeH₄, GeF₄, CH₄, CF₄, AsF₅, PF₃ and PF₅. The plasma source 206 may generate the plasma 240 by exciting and ionizing the gas provided to the processing chamber 200. Ions in the plasma 240 may be attracted across the plasma sheath 242 by different mechanisms. In the embodiment of FIG. 2A, a bias source 290 is coupled to the substrate support 234 configured to bias the substrate 238 to attract ions 202 from the plasma 240 across the plasma sheath 242. The bias source 290 may be a DC power supply to provide a DC voltage bias signal or an RF power supply to provide an RF bias signal.

It is believed that the plasma sheath modifier 208 modifies the electric field within the plasma sheath 242 to control a shape of the boundary 241 between the plasma 240 and the plasma sheath 242. The boundary 241 between the plasma 240 and the plasma sheath 242 may have a convex shape relative to the plane 251. When the bias source 290 biases the substrate 238, ions 202 are attracted across the plasma sheath 242 through the gap 216 defined between the modifiers 212, 214 through a large range of incident angles. For instance, ions 202 following trajectory path 271 may strike the substrate 338 at an angle of positive θ (+θ) relative to the plane 251. Ions following trajectory path 270 may strike perpendicularly on the substrate 238 at about an angle of about 90 degrees relative to the same plane 251. Ions following trajectory path 269 may strike the substrate 238 at an angle of negative θ (−θ) relative to the plane 251. Accordingly, the range of incident angles may be between about positive θ (+θ) and about negative θ (−θ), centered about 90 degrees. In addition, some ion trajectories paths such as paths 269 and 271 may cross each other. Depending on a number of factors including, but not limited to, the horizontal spacing (G) between the modifiers 212 and 214, the vertical spacing (Z) of the plasma sheath modifier 208 above the plane 251, the dielectric constant of the modifiers 212 and 214, and other plasma process parameters, the range of incident angles (θ) may be between +60 degree and −60 degree centered about 0 degree. Hence, small three dimensional structures on the substrate 238 may be treated uniformly by the ions 202. For example, sidewalls 247 of the feature 244, which may be utilized to form a fin structure for FINFET devices, having an exaggerated size for clarity of illustration, may be more uniformly treated by the ions 202, along with a top surface 249.

Referring to FIG. 2B, instead of a pair of modifiers 212, 214 depicted in FIG. 2A, at least three modifiers 1400, 1402, 1404 are used to control the ions with desired angular distribution to the substrate 238. By arranging the outer two modifiers 1400, 1404 on a common plane equally shaped a distance Za above the substrate 238, the same vertical plane (Za), and by maintaining equal horizontal spacing G1, G2 between the modifiers 1400, 1402, 1404, a symmetric bimodal angular spread of ions, centered about +/−θ (+θ and −θ) degrees may be obtained. As described above, the incidental angles ions doped onto the substrate 238 may be modified by varying the vertical spacing between the outer modifiers 1400, 1404 and the middle modifier 1402, so as to vary the gap angles. The angular ion spread can be modified by varying the horizontal spacing (G1, G2) between the modifiers 1400, 1402, 1404, so as to vary the gap width defined by the horizontal spacing (G1, G2). An asymmetric distribution can be created by making Za different than Zb, by choosing G1 different than G2, or a combination of both actions. In one embodiment, the angular ion spread can be modified from between about 0 degree and about 30 degrees from the center to only treat or implant ions into one side of a structure.

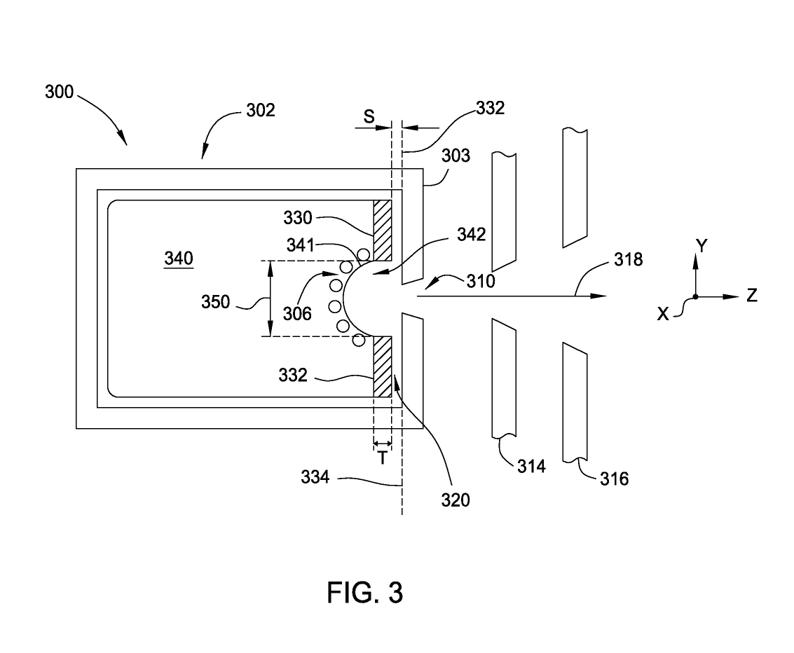

FIG. 3 depicts another embodiment of an ion processing chamber 300 that may be utilized to dope ions into a substrate with desired and variable incident angles. The processing chamber 300 includes an arc chamber 302 having a sidewall 303 with an extraction aperture 310. The processing chamber 300 further includes a plasma sheath modulator 320 to control a shape of a boundary 341 between the plasma 340 and the plasma sheath 342 proximate the extraction aperture 310. An extraction electrode assembly extracts ions 306 from the plasma 340 and accelerates them across the plasma sheath 342 to desired extraction energy of a well-defined ion beam 318. The extraction electrode assembly may include the sidewall 303 functioning as an arc slot electrode, a suppression electrode 314 and a ground electrode 316. The suppression electrode 314 and the ground electrode 316 each have an aperture aligned with the extraction aperture 310 for extraction of the well-defined ion beam 318. To aid with explanation, a Cartesian coordinate system is defined where the ion beam 318 travels in the Z direction. The X-Y plane is perpendicular to the Z direction which can change depending on the direction of the ion beam 318.

In the embodiment of FIG. 3, the plasma sheath modulator 420 includes a pair of modifiers 330, 332 positioned in the arc chamber 302. In other embodiments, the modulator 320 may include one modifier. The modifiers 330, 332 may be fabricated of quartz, alumina, boron nitride, silicon, silicon carbide, graphite, glass, porcelain, silicon nitride and the like. The pair of modifiers 330, 332 may be a pair of sheets having a thin, flat shape. In other embodiments, the pair of modifiers 330, 332 may be other shapes such as tube shaped, wedge shaped, and/or have a beveled edge. The pair of modifiers 330, 332 defines a gap 350 there between having spacing (G). The pair of modifiers 330, 332 may also be positioned a vertical spacing (S) above the plane 332 defined by an interior surface of the sidewall 303 having the extraction aperture 310.

In operation, a feed gas (not illustrated) is supplied to the arc chamber 302. Examples of a feed gas include, but are not limited to, BF₃, BI₃N₂, Ar, PH₃, AsH₃, B₂H₆, H₂, Xe, SF₆, C₂F₆, CHF₃, Kr, Ne, He, SiH₄, SiF₄, GeH₄, GeF₄, CH₄, CF₄, AsF₅, PF₃ and PF₅. The feed gas may originate from a gas source or may be vaporized from a solid source depending on the desired species. The feed gas is ionized in the arc chamber 302 to generate plasma. Those skilled in the art will recognize differing types of ion sources that generate plasma in differing ways, such as an indirectly heated cathode (IHC) source, a Bernas source, a RF source, a microwave source, and an electron cyclotron resonance (ECR) source. An IHC source generally includes a filament positioned in close proximity to a cathode, and also includes associated power supplies. The cathode (not illustrated) is positioned in the arc chamber 302. As the filament is heated, electrons emitted by the filament are accelerated towards the cathode to provide for heating of the cathode. The heated cathode, in turn, provides electrons into the arc chamber that have ionizing collisions with the gas molecules of the feed gas to generate plasma.

An extraction electrode assembly including the sidewall 303, the suppression electrode 314 and the ground electrode 316 extracts ions 306 from the plasma 340 in the arc chamber 302 into the well-defined ion beam 318. The ions 306 are accelerated across the boundary 341 and the plasma sheath 342 through the gap 350 between the pair of modifiers 330, 332. The sidewall 303 functioning as an arc source electrode may be biased by a power supply to the same large potential as the arc chamber 302. The suppression electrode 314 may be biased at a moderately negative value to prevent electrons from entering back into the arc chamber 302. The ground electrode 315 may be at ground potential. The strength of the electric field generated by the electrode assembly may be tuned to achieve a desired beam current and energy.

Advantageously, the plasma sheath modulator 320 controls a shape of the boundary 341 between the plasma 340 and the plasma sheath 342 proximate the extraction aperture 310. To control the shape of the boundary 341 the plasma sheath modulator 320 modifies or influences the electric field within the plasma sheath 342. When the plasma sheath modulator 320 includes the pair of modifiers 330, 332, the boundary 341 may have a concave shape relative to the plasma 340 as illustrated in FIG. 3. Depending on a number of factors including, but not limited to, the horizontal spacing (G) between the modifiers 330, 332, the vertical spacing (S) of the modifiers 330, 332 above the plane of the substrate or substrate support, the material and thickness thereof of the modifiers 330, 332, and other process parameters of the ion source, the shape of the boundary 341 may be controlled.

The shape of the boundary 341 between the plasma 340 and the plasma sheath 342, together with the electric field gradients within the plasma sheath 342, control parameters of the ion beam. For example, the angular spread of the ions 306 can be controlled to assist with ion beam focusing. For instance, with the boundary 341 having a concave shape relative to the plasma, there is a large angular spread of ions accelerated across the boundary to assist with beam focusing. In addition, the ion beam current density of the ion beam 318 can also be controlled. For example, compared to the boundary 341 of one conventional ion source, the boundary 341 has a larger area to extract additional ions. Hence, the additional extracted ions contribute to an increased ion beam current density. Accordingly, with all other parameters being equal, the shape of the boundary 341 can provide a focused ion beam with a high ion beam current density. Furthermore, the emittance of the ion beam can also be controlled by controlling the shape of the boundary 341. Consequently, the beam quality of the extracted ion beam can be well defined for a given particle density and angular distribution.

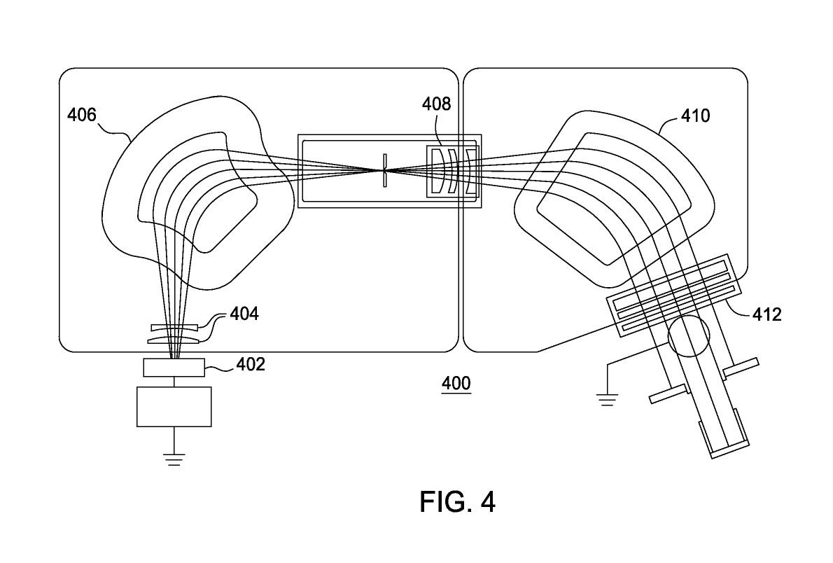

FIG. 4 depicts a conventional ion implanting processing chamber 500 that may be utilized to dope ions into certain regions of the substrate. The ion implanting processing chamber 400 includes an ion source 402, extraction electrodes 404, a 90 degree magnet analyzer 406, a first deceleration (D1) stage 408, a magnet analyzer 410, and a second deceleration (D2) stage 412. The deceleration stages D1, D2 (also known as “deceleration lenses”) are each comprised of multiple electrodes with a defined aperture to allow an ion beam to pass therethrough. By applying different combinations of voltage potentials to the multiple electrodes, the deceleration lenses D1, D2 can manipulate ion energies and cause the ion beam to hit a target wafer at a desired energy which implants ions into a substrate. The above-mentioned deceleration lenses D1, D2 are typically electrostatic triode (or tetrode) deceleration lenses.

FIG. 5 is a cross sectional view of an illustrative processing chamber 500 suitable for conducting an etching process as further described below. The chamber 500 may be configured to remove material from a material layer disposed on a substrate surface. The chamber 100 is particularly useful for performing the plasma assisted dry etch process. The processing chamber 500 may be a Siconi™, Capa™, or Frontier™ chamber, which is available from Applied Materials, Santa Clara, Calif. It is noted that other vacuum processing chambers available from other manufactures may also be adapted to practice the present invention.

The processing chamber 500 includes a chamber body 512, a lid assembly 540, and a support assembly 580. The lid assembly 540 is disposed at an upper end of the chamber body 512, and the support assembly 580 is at least partially disposed within the chamber body 512.

The chamber body 512 includes a slit valve opening 514 formed in a sidewall thereof to provide access to the interior of the processing chamber 500. The slit valve opening 514 is selectively opened and closed to allow access to the interior of the chamber body 512 by a wafer handling robot (not shown).

In one or more implementations, the chamber body 512 includes a channel 515 formed therein for flowing a heat transfer fluid therethrough. The chamber body 512 can further include a liner 520 that surrounds the support assembly 580. The liner 520 is removable for servicing and cleaning. In one or more embodiments, the liner 520 includes one or more apertures 525 and a pumping channel 529 formed therein that is in fluid communication with a vacuum system. The apertures 525 provide a flow path for gases into the pumping channel 529, which provides an egress for the gases within the processing chamber 500.

The vacuum system can include a vacuum pump 530 and a throttle valve 532 to regulate flow of gases through the processing chamber 500. The vacuum pump 530 is coupled to a vacuum port 531 disposed in the chamber body 512 and therefore, in fluid communication with the pumping channel 529 formed within the liner 520. The lid assembly 540 includes at least two stacked components configured to form a plasma volume or cavity therebetween. In one or more embodiments, the lid assembly 540 includes a first electrode 543 (“upper electrode”) disposed vertically above a second electrode 545 (“lower electrode”) confining a plasma volume or cavity 550 therebetween. The first electrode 543 is connected to a power source 552, such as an RF power supply, and the second electrode 545 is connected to ground, forming a capacitance between the two electrodes 543,545.

In one or more implementations, the lid assembly 540 includes one or more gas inlets 554 (only one is shown) that are at least partially formed within an upper section 556 of the first electrode 543. The one or more process gases enter the lid assembly 540 via the one or more gas inlets 554. The one or more gas inlets 554 are in fluid communication with the plasma cavity 550 at a first end thereof and coupled to one or more upstream gas sources and/or other gas delivery components, such as gas mixers, at a second end thereof. In one or more embodiments, the first electrode 543 has an expanding section 555 that houses the plasma cavity 550.

In one or more implementations, the expanding section 555 is an annular member that has an inner surface or diameter 557 that gradually increases from an upper portion 555A thereof to a lower portion 555B thereof. As such, the distance between the first electrode 543 and the second electrode 545 is variable. The varying distance helps control the formation and stability of the plasma generated within the plasma cavity 550. A plasma generated in the plasma cavity 550 is defined in the lid assembly 540 prior to entering into a processing region 541 above the support assembly 580 wherein the substrate is proceed, the plasma is considered as a remote plasma source that generated remotely from the processing region 541.

The lid assembly 540 can further include an isolator ring 560 that electrically isolates the first electrode 543 from the second electrode 545. The lid assembly 540 can further include a distribution plate 570 and blocker plate 575 adjacent the second electrode 545. The second electrode 545, distribution plate 570 and blocker plate 575 can be stacked and disposed on a lid rim 578 which is connected to the chamber body 512. In one or more implementations, the second electrode or top plate 545 can include a plurality of gas passages or apertures 565 formed beneath the plasma cavity 550 to allow gas from the plasma cavity 550 to flow therethrough. The distribution plate 570 is substantially disc-shaped and also includes a plurality of apertures 572 or passageways to distribute the flow of gases therethrough. In one or more embodiments, the distribution plate 570 includes one or more embedded channels or passages 574 for housing a heater or heating fluid to provide temperature control of the lid assembly 540. The blocker plate 575 includes a plurality of apertures 576 to provide a plurality of gas passages from the second electrode 545 to the distribution plate 570. The apertures 576 can be sized and positioned about the blocker plate 575 to provide a controlled and even flow distribution of gases to the distribution plate 570.

The support assembly 580 can include a support member 585 to support a substrate (not shown in this view) for processing within the chamber body 512. The support member 585 can be coupled to a lift mechanism 583 through a shaft 587 which extends through a centrally-located opening 514 formed in a bottom surface of the chamber body 512. The lift mechanism 583 can be flexibly sealed to the chamber body 512 by a bellows 588 that prevents vacuum leakage from around the shaft 587.

In one embodiment, the electrode 581 that is coupled to a plurality of RF power bias sources 584, 586. The RF bias power sources 584, 586 are coupled between the electrode 581 disposed in the support member 585. The RF bias power excites and sustains a plasma discharge formed from the gases disposed in the processing region 541 of the chamber body.

In the embodiment depicted in FIG. 5, the dual RF bias power sources 584, 586 are coupled to the electrode 581 disposed in the support member 585 through a matching circuit 589. The signal generated by the RF bias power sources 584, 586 is delivered through matching circuit 589 to the support member 585 through a single feed to ionize the gas mixture provided in the plasma processing chamber 500, thereby providing ion energy necessary for performing a deposition or other plasma enhanced process. The RF bias power sources 584, 586 are generally capable of producing an RF signal having a frequency of from about 50 kHz to about 200 MHz and a power between about 0 Watts and about 5000 Watts. Additional bias power sources may be coupled to the electrode 581 to control the characteristics of the plasma as needed.

The support member 585 can include bores 592 formed therethrough to accommodate lift pins 593, one of which is shown in FIG. 5. Each lift pin 593 is constructed of ceramic or ceramic-containing materials, and are used for substrate-handling and transport. The lift pin 593 is moveable within its respective bore 592 when engaging an annular lift ring 595 disposed within the chamber body 512. The support assembly 580 can further include an edge ring 196 disposed about the support member 585.

The temperature of the support assembly 580 can be controlled by a fluid circulated through a fluid channel 598 embedded in the body of the support member 585. In one or more implementations, the fluid channel 598 is in fluid communication with a heat transfer conduit 599 disposed through the shaft 587 of the support assembly 580. The fluid channel 598 is positioned about the support member 585 to provide a uniform heat transfer to the substrate receiving surface of the support member 585. The fluid channel 598 and heat transfer conduit 599 can flow heat transfer fluids to either heat or cool the support member 585. Any suitable heat transfer fluid may be used, such as water, nitrogen, ethylene glycol, or mixtures thereof. The support assembly 580 can further include an embedded thermocouple (not shown) for monitoring the temperature of the support surface of the support member 585. For example, a signal from the thermocouple may be used in a feedback loop to control the temperature or flow rate of the fluid circulated through the fluid channel 598.

The support member 585 can be moved vertically within the chamber body 512 so that a distance between support member 585 and the lid assembly 540 can be controlled. A sensor (not shown) can provide information concerning the position of support member 585 within chamber 500.

A system controller (not shown) can be used to regulate the operations of the processing chamber 500. The system controller can operate under the control of a computer program stored on a memory of a computer. The computer program may include instructions that enable the preclean process described below to be performed in the processing chamber 500. For example, the computer program can dictate the process sequencing and timing, mixture of gases, chamber pressures, RF power levels, susceptor positioning, slit valve opening and closing, wafer cooling and other parameters of a particular process.

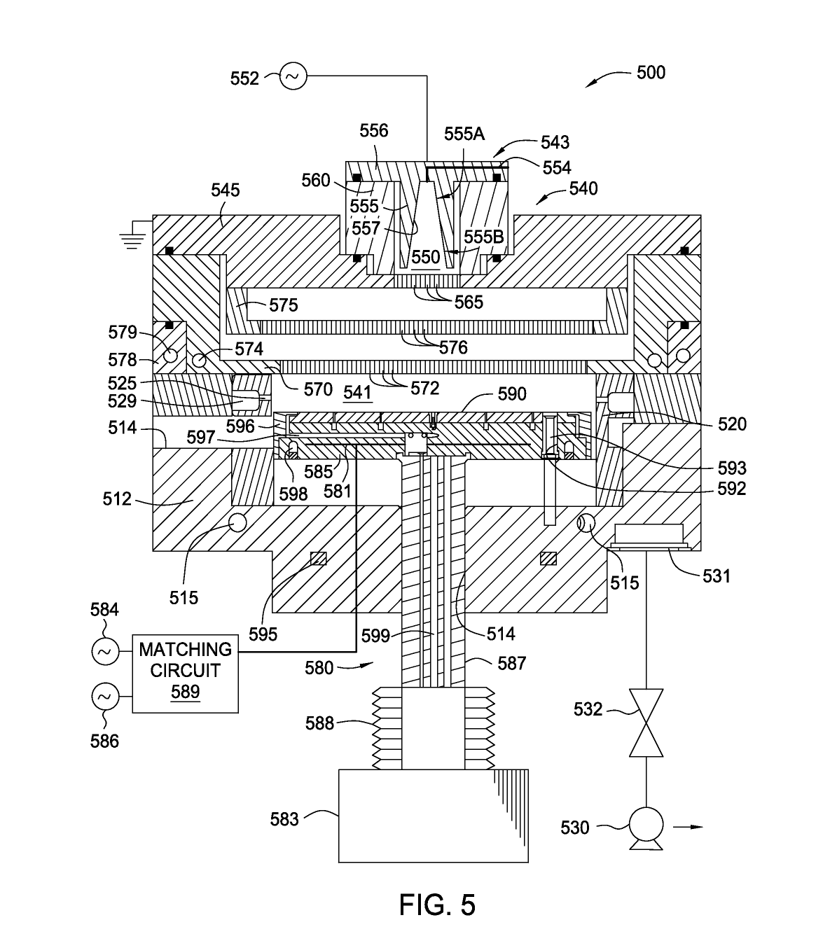

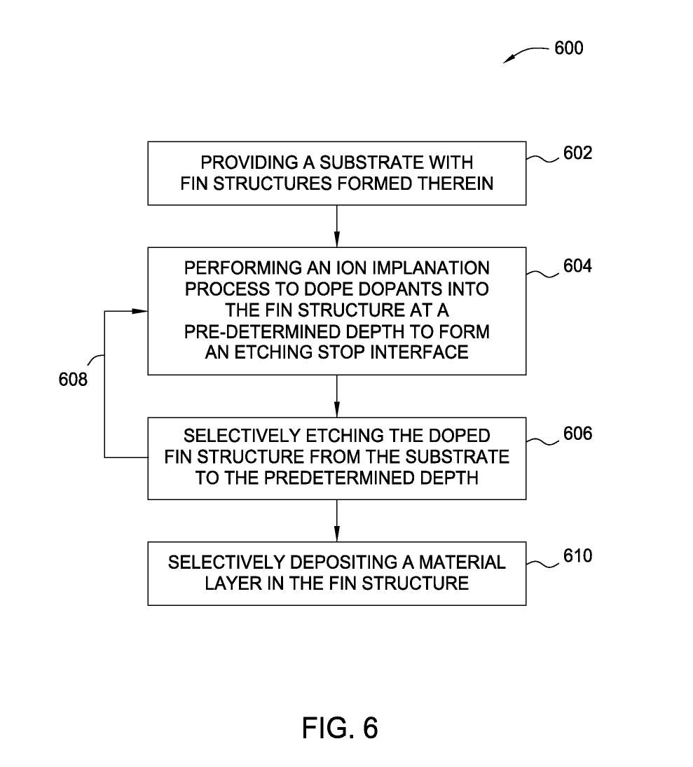

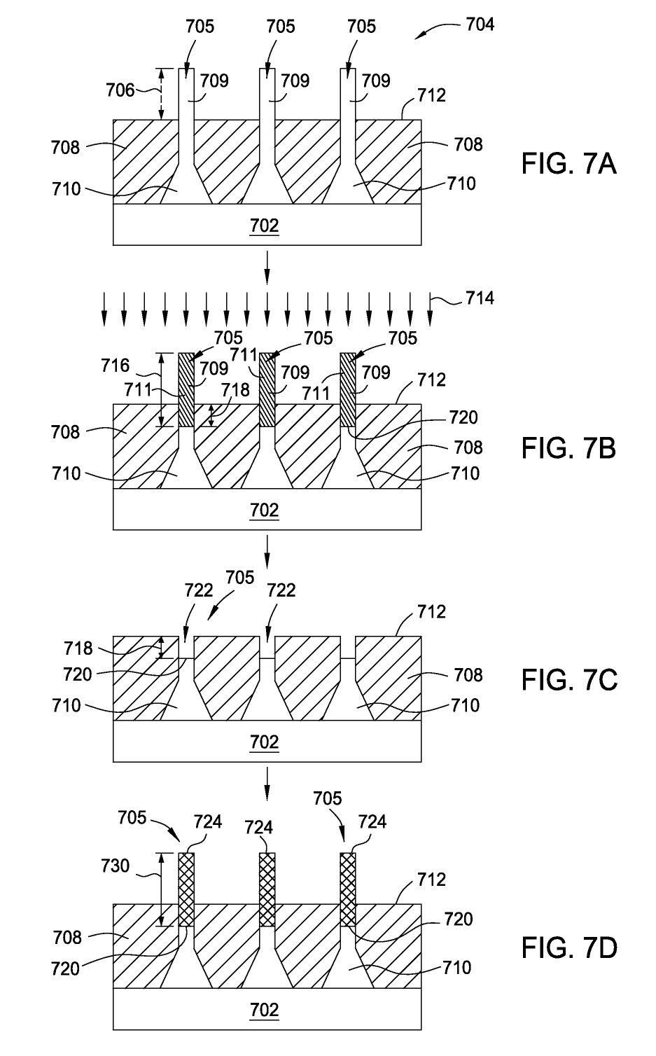

FIG. 6 is a flow diagram of one implementation of utilizing an ion implantation method 600 utilized to form an etching stop interface in a structure, such as a fin structure, that may be later form the structure with different materials on different regions of the structure. The structure may be a three dimensional protrusion structure extending outward from the substrate, such as a fin structure, a gate structure, a contact structure, or any other suitable structures utilized in semiconductor applications. FIGS. 7A-7D are schematic cross-sectional views of a portion of a composite substrate 702 corresponding to various stages of the method 600. The method 600 may be utilized to form fin structures on a substrate having desired materials formed on different regions of the fin structure which may later be utilized to form a fin field effect transistor (FinFET) for three dimensional (3D) stacking of semiconductor chips. Alternatively, the method 600 may be beneficially utilized to form other types of structures.

The method 600 begins at block 602 by providing a substrate, such as the substrate 702 depicted in FIG. 7A. The substrate may have a plurality of structures 704, such as fin structures 705, formed thereon, as shown in FIG. 7A. In one embodiment, the substrate 702 may be made of a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 702 may have various dimensions, such as 200 mm, 300 mm, 450 mm or other diameter, as well as, being a rectangular or square panel. Unless otherwise noted, embodiments and examples described herein are conducted on substrates with a 200 mm diameter, a 300 mm diameter, or a 450 mm diameter substrate. In the embodiment wherein a SOI structure is utilized for the substrate 702, the substrate 702 may include a buried dielectric layer disposed on a silicon crystalline substrate. In the embodiment depicted herein, the substrate 702 may be a crystalline silicon substrate. Moreover, the substrate 702 is not limited to any particular size or shape. The substrate 702 may be a round substrate having a 200 mm diameter, a 300 mm diameter or other diameters, such as 450 mm, among others. The substrate 702 may also be any polygonal, square, rectangular, curved or otherwise non-circular workpiece, such as a polygonal glass substrate used in the fabrication of flat panel displays.

The fin structures 704 may be a structure extending outward and protruding from the substrate 702. The fin structure 705 may have an upper portion 709 connected to a lower portion 710. Although the lower portion 710 depicted in FIG. 7A has a flared-out configuration, it is noted that the profile of the fin structures 705, including the upper portion 709, formed in the substrate 702 may have different forms, including sidewalls that are substantially straight, flared out, upward tapered or downward tapered-down, or angled profiles, special sidewall features, overhang or undercut structures, or other profiles as needed.

In one embodiment, the fin structures 705 may be formed in the substrate 702 by etching the substrate 702 to form recess structures between each of the fin structures 705. A portion of the recess structures are then filled with insulating materials to form shallow trench isolation (STI) structures 708 so as to facilitate forming the fin structures 705 therebetween for the fin field effect transistors (FinFET) manufacture process. In one embodiment, the upper portion 709 may protrude from a surface 712 of the shallow trench isolation (STI) structures 708 having a height 706 from the surface 712 from the shallow trench isolation (STI) structures 708. It is noted that the height 706 of each of the fin structure 705 protruding from the surface 712 of the shallow trench isolation (STI) structures 708 may or may not be exactly the same, due to manufacturing deviations, microloading effect, or other issues.

As the fin structure 705 is formed by etching the substrate 702, thus, the fin structure 705 may be of the same material as the substrate 702, which may be a silicon containing material. In the embodiment depicted herein, the substrate 702 is a silicon substrate so that the fin structure 705 formed therefrom is also a silicon material.

In one embodiment, the insulating material utilized to form the shallow trench isolation (STI) structures 708 may be a dielectric material, such as silicon oxide material. The insulating material may be formed by a plasma enhanced chemical vapor deposition (CVD), a flowable chemical vapor deposition (CVD), a high density plasma (HDP) chemical vapor deposition (CVD) process, atomic layer deposition (ALD), cyclical layer deposition (CLD), physical vapor deposition (PVD), or the like as needed. In one embodiment, the insulating material is formed by a flowable or plasma enhanced chemical vapor deposition (CVD).

At block 604, a directional plasma process (or an ion doping/implantation process) is performed to dope, coat, treat, implant, insert or modify certain film/surface properties on certain locations of fin structure 705 to form a treated region 711 in the fin structures 705, as shown in FIG. 7B. The directional plasma process utilizes directional and/or incident ions 714 with particular selected angles to predominantly modify film/surface properties on predominantly a portion of fin structure 705, such as the upper portion 709 of the fin structure 705, forming the treated region 711 in the fin structure 705. The dopants utilized to treat in the treated region 711 change and/or modify part of the film properties of the fin structure 705, so as to provide a film property of the treated region 711 different from a film property of the lower portion 710 which receives significantly less dopants compared to the upper portion 709 during the ion doping/treatment process.

The directional plasma process or ion implantation process may be performed in a directional plasma processing chamber, such as the processing chamber 300, 400, 500 depicted in FIG. 2A-2B, 3 or 4, or other suitable conventional ion implantation/doping processing tool. The directional plasma process is performed by implanting ions 714 as shown in FIG. 7B, with desired incident angles, to a selected region, such as the upper portion 709 of the fin structures 705 to form the treated region 711 with desired film property change. While forming the treated region 711, non-selected region, such as the power portion 710 of the fin structure 705 does not receive significant amount of ions/dopants, and thus fails to form a treated region. The ions, which include a desired type of atoms, may be doped into the upper portion 709 of the fin structures 705, forming the treated region 711 creating an interface 720 facing with the unchanged/unmodified lower region 710 of the fin structure 705. The ions may treat, bombard, modify atom/bonding structures in the upper portion 709 of the fin structures 705, so as to result in film bonding structures different from other regions, such as the lower region 710 of the fin structure 705 which do not receive ion treatment. The treated region 711 may form the interface 720 between the treated and untreated regions 711, 710. In one embodiment, the interface 720 may be configured to be form having a depth 718 between about 20 nm and about 100 nm below the surface 712 of the shallow trench isolation (STI) structures 708, making the overall treated region 711 having a height 716 between about 50 nm and about 200 nm.

In one embodiment, the ions 714 generated from the directional plasma process, or the ion implantation/doping process, are configured to have an incident angle between about 0 degrees and about 60 degrees. With the desired and predetermined incident and directional angles, the ions 714 may mainly be implanted into the predetermined regions, e.g., the upper portion 709 of the fin structure 705, with controlled doping incident angles, rather than only from the top of the fin structure 705 or globally formed everywhere on the substrate, as conventional doping/implantation processes typically do. By doing so, some other regions, such as the lower portion 710 of the fin structure 705 that is not intended to be doped, plasma treated, or be deposited thereon during the directional plasma process, may be selectively and/or intentionally left out during (i.e., not subject to) the directional plasma process, that the treated portion 711 is formed substantially only on the upper portion 709 of the fin structure 705. The directional plasma process may alter the fin structure 705 to form the treated region 711 to form desired doping profile/film bonding structure change as needed, providing the treated region 711 with altered film properties that enable obtaining different process results during the subsequent etching processes.

In one embodiment, an inert gas may be utilized to perform the ion implantation method to form the treated layer 711. Suitable examples of the inert gas include Ar, He, Kr, Ne, Xe or the like. When an inert gas is selected as the ion treatment gas, the atoms from the inert gas physically bombard and collide with the atoms made up the fin structure 705. As the implantation power applied during the implantation process may provide momentum to the atoms from the inert gas, so when colliding with the atoms from the fin structure 705, the bonding structures in the fin structure 705 may be damaged and rearranged, thus resulting a damaged/loose bonding structures to the areas selected to be implanted, such as the upper region 709, forming the treated region 711 with damaged/loose bonding structure, as compared to the untreated lower region 710. As the atoms from the inert gas damage and loosen the bonding structures present in the upper region 709, the resultant treated layer 711 may also have a damaged bonding structure, which may be easily etched and removed away by an etching process. The resultant treated layer 711 defines the interface 720 which serves as a block layer/etching stop layer that prevents the lower portion 710 from overetching when reaching to the interface 720 during an etching process. In the embodiment wherein the fin structure 705 is made from a crystalline silicon material, the atoms from the insert gas may collide the lattice structure of the silicon atoms in the crystalline silicon material of the fin structure 705, destroying and damaging the lattice structure of the silicon material, thus amorphizating the silicon material and turning it into an amorphous silicon layer in the area above the defined interface 720. In this example, the treated region 711 as formed in the fin structure 705 turns mostly into amorphous silicon layers, as a result of the collisions of inert gas to the fin structure 705 during the ion implantation/treatment process. By doing so, the amorphous type treated layer 711 may be easily attacked and etched away in the subsequent etching process, providing an etching rate faster than the etching rate for etching the untreated lower portion 710, thereby providing a good etching selectivity during the subsequent etching process.

In one embodiment, inert gas with high molecular weight, such as Ar, Ne, or Kr, may be selected to perform the ion implantation/treatment process. As these elements have relatively high molecular weight, a relatively higher collision power may be obtained when striking the surface of the fin structure 705 so as to provide an efficient collision to alter and damage the lattice structure of the fin structure 705 to facilitate the following etching process.

In another embodiment, a doping gas mixture including a p-type or a n-type dopant gas may be utilized in the ion implantation/treatment process. The doping gas mixture may implant p-type or n-type dopants into the fin structure 705, forming the treated region 711 with n-type dopants or p-type dopants doped therein. The n-type or p-type dopants formed in the treated region 711 may alter a film property, such as different etching rate, compared to the lower region 710 of the fin structure 205 which has essentially no ion treatment. The dopants doped in the treated region 711 define the interface 720 that may serve as an etching stop layer at the subsequent etching process. The dopants as implanted may change the lattice structures of the substrate, thereby naturally forming a block layer in the substrate, defining the treated region 11, which has different atomic structures and properties than the underlying untreated portion 710, rendering a high selectivity for the etching process. As such, aggressive etchants from an etching process may be prevented from further attacking the substrate when reaching the interface 710 formed in the fin structure 705, thereby allowing the fin structure 705 to remain as formed with desired profile and dimension control.

During the ion implantation/treatment process, dopants with different ion properties are implanted and collided with the substrate 402. The dopants from the treated region 711, which serves as a block layer/etching stop layer that prevents the lower portion 710 from overetching when reaching to the interface 720. It is believed that the dopants implanted into the treated region 711 may react with the etchant at a faster (or slower) etching rate to enhance the etching selectivity, as compared to the undoped lower portion 710 of the fin structure 705. By utilizing the etching rate difference between the treated region 711 and lower portion 710 of the fin structure 705, an etching stop at the interface 720 may be formed to efficiently control an etching stopping point during the etching process. For example, when n-type dopants are selected to be impinged into the silicon lattice structures to form the treated region 711 on the fin structure 705, the n-type dopants may be inserted into the interstitial sites between the silicon atoms in the lattice structure, thereby changing the Fermi level of Si substrate with n-type dopants, resulting in the bandgap of n-doped silicon in the treated region 711 being close to the conduction band. It is believed n-type dopants doped in the treated region 711 may provide free electrons during the etching process. As such, when a halogen containing gas, such as a chlorine containing gas, is utilized during the etching process, the free electron provided from the n-type dopants in the silicon rapidly reacts with the chlorine containing gas through an electron transfer process (i.e., as chlorine containing gas is known to have it high tendency for grabbing electron during a chemical reaction), thereby efficiently increasing silicon substrate etch rate. As compared to the undoped lower portion 710 (e.g., intrinsic silicon areas) which does not have incorporated n-type dopants, the lack of free electrons as a media for promoting chemical reaction may result in a significantly lower etching rate, thereby creating a reaction barrier at the interface 720 which inhibits etching of the undoped lower portion 710. Therefore, by selecting proper ions to be doped in the fin structure 705, an efficient etching stop layer may be created to enable an etching process with high selectivity. Thus, the high electivity of the etching process may assist forming desired etch front profile and to minimize etch depth variations in areas of different pattern densities to eliminate undesired microloading effects and obtain a recess structure profile (e.g., trenches, recess structures, features, vias, holes, or the like) in the fin structure 705 with desired dimensions (e.g., depth and width of the structure) and sidewall/bottom management.

In one embodiment, the dopants selected to be implanted into the substrate fin structure 705 may be n-type dopants, such as Sb, As, P and N. In the embodiment wherein the n-type dopants are utilized, Sb may be selected as the dopant as the higher molecular weight of Sb may allow the dopants to stay at a desired lattice position in the substrate without undesired drift during an etching process. In some embodiments, p-type dopants, such as B, Al, Ga, and In, may be utilized based on different process requirements.

In one embodiment, the directional plasma process may utilize a moving stage to support and move the substrate 702 to expose the fin structure 705 at different angles with respect to the incident ions 705. Moving the stage and the substrate 705 disposed thereon relative to the angled ion beams allows for an interactive ion scanning/treating process that enables certain area of the substrate 705 to be linearly, circularly, or regularly treated at a predetermined mode continuously or repetitively.

Several process parameters may be controlled during the directional plasma process. The ion doping gas mixture or inert gas may be supplied into the processing chamber at a flow rate between about 10 sccm and about 200 sccm. Suitable gases for supplying in the ion doping gas mixture include AsH₃, GaH₃, SiH₄, SiF₄, GeH₄, GeF₄, CH₄, CF₄, AsF₅, PF₃, PF₅, B₂H₆, BH₃ and the like. Suitable examples of the inert gas include Ar, He, Kr, Ne or the like. Some carrier gases, such as H₂, N₂, N₂O, NO₂, or the like, may also be supplied into the gas mixture as needed. The chamber pressure is generally maintained between about 0.1 mTorr and about 100 mTorr, such as about 10 mTorr. A RF power, such as capacitive or inductive RF power, DC power, electromagnetic energy, or magnetron sputtering, may be supplied into the processing chamber 200 to assist dissociating the gas mixture during processing. Ions generated by the dissociative energy may be accelerated toward the substrate using an electric field produced by applying a DC or RF electrical bias to the substrate support or to a gas inlet above the substrate support, or both. In some embodiments, the ions may be subjected to a mass selection or mass filtration process, which may comprise passing the ions through a magnetic field aligned orthogonal to the desired direction of motion. The electric field provided by the RF power may be capacitively or inductively coupled for purposes of ionizing the atoms, and may be a DC discharge field or an alternating field, such as an RF field. Alternately, microwave energy may be applied to the ion implanting gas mixture containing any of these elements to generate ions. In some embodiments, the gas containing energetic ions may be a plasma. An electrical bias (peak to peak voltage) of between about 50 V and about 10000 V, such as about 4000V is applied to the substrate support, the gas distributor, or both, to accelerate the ions toward the substrate surface with the desired energy. In some embodiments, the electrical bias is also used to ionize the ion implantation processing gas. In other embodiments, a second electric field is used to ionize the process gas. In one embodiment, a RF field with a frequency of about 2 MHz is provided to ionize the ion implantation processing gas and bias the substrate support at a power level between about 100 W and about 10000 W. The ions thus produced will generally be accelerated toward the substrate by biasing the substrate or a gas distributor as described above.

In some embodiments, the power used to generate ions may be pulsed. Power may be applied to the plasma source for a desired time, and then discontinued for a desired time. Power cycling may be repeated for a desired number of cycles at a desired frequency and duty cycle. In some embodiments, the plasma may be pulsed at a frequency between about 1 Hz and about 50,000 Hz, such as between about 5000 Hz and about 10000 Hz. In other embodiments, the plasma pulsing may proceed with a duty cycle (ratio of powered time to unpowered time per cycle) between about 10% and about 90%, such as between about 30% and about 70%. In one embodiment, the RF source power may be supplied at between about 100 Watts to about 5000 Watts, and the bias power may be supplied at between about 50 Watts and about 11000 Watts. The process temperature may be controlled at between about 5 degrees Celsius and about 650 degrees Celsius.

At block 606, after the directional plasma process or ion doping/implantation process, an etching process may be performed to remove the treated region 711 from the fin structure 705, as shown in FIG. 7C, forming openings 722 above the interface 720 in the fin structure 705. The etching gas mixture is supplied into a processing chamber with a remote plasma source, such as the processing chamber 500 depicted in FIG. 5, to etch the treated region 711, until the interface 720 is exposed, and thus exposing the underlying lower portion 710. As discussed above, the interface 720 servers as an etching stop layer during the etching process of the treated region 711.

The etching gas mixture selected to etch the treated region 711 includes at least a hydrogen containing gas, such as H₂, H₂O, H₂O₂, or the like supplied from a remote plasma source, or from a plasma maintained in the processing chamber as needed. The plasma supplied from the remote source may provide a gentle source that may mildly and gradually etch the treated region 711 without overly attacking the fin structure 705. In one example, a H₂ gas is utilized to form a remote plasma source to etch the treated region 711.

In the implementation wherein the treated region 711 includes n-type dopants or p-type dopants formed therein, a hydrocarbon containing gas having a formula CₓH_{y}, wherein x and y are integers ranging from 1 to 8 and 4 to 18 respectively, may be used to etch the treated region 711. Suitable examples of the hydrocarbon containing gas include methane (CH₄), ethane (C₂H₆), propane (C₃H₈), butane (C₄H₁₀), pentane (C₅H₁₂), hexane (C₆H₁₄), propene, ethylene, propylene, butylene, pentene, combinations thereof and the like.

While supplying the etching gas mixture, an inert gas may also be supplied into the etching gas mixture to assist the profile control as needed. Examples of the inert gas supplied in the gas mixture include Ar, He, Ne, Kr, Xe or the like. In one embodiment, the hydrocarbon gas supplied in the etching gas mixture may be maintained at a flow rate by volume between about 30 sccm and about 150 sccm. The optional inert gas may be supplied to the processing chamber at a flow rate by volume between about 50 sccm and about 300 sccm.

After the etching gas mixture is supplied to the processing chamber mixture, a RF power of remote plasma source may be supplied in the etching gas mixture for between about 200 Watts and about 3000 Watts. In some examples, a RF source power may also be supplied to form a plasma from the etching gas mixture within the processing chamber. The RF source power may be supplied at the etching gas mixture between about 1000 Watts and about 3000 Watts and at a frequency between about 400 kHz and about 60 MHz. A RF bias power may also be supplied as needed. The RF bias power may be supplied at between about 300 Watts and about 1500 Watts. In one embodiment, the RF source power may be pulsed with a duty cycle between about 10 to about 95 percent at a RF frequency between about 500 Hz and about 10 MHz.

Several process parameters may also be controlled while supplying the etching gas mixture to perform the etching process. The pressure of the processing chamber may be controlled at between about 0.5 milliTorr and about 500 milliTorr, such as between about 2 milliTorr and about 10 milliTorr. A substrate temperature is maintained between about 15 degrees Celsius to about 300 degrees Celsius, such as greater than 50 degrees Celsius, for example between about 60 degrees Celsius and about 90 degrees Celsius. It is believed that high temperature, temperature greater than 50 degrees Celsius, helps reduce the amount of etching byproduct deposition on the substrate. The etching process may be performed for between about 30 seconds and about 180 seconds to etch the metal layer 708 with a thickness for between about 200 Å and about 1200 Å.

It is noted that the ion implantation process performed at 604 and the etching process at 606 may be repeatedly and cyclically formed, as shown in the loop 608, to incrementally and gradually remove and etch away the treated region 711 substantially without attacking other regions of the fin structure 705.

At block 610, after the etching process and the treated region 711 is removed from the fin structure 705, a selective deposition process may then performed to selectively form a material layer 724 in the openings 722 defined above the interface 720, as shown in FIG. 7D. The material layer 724 may be selectively formed on the interface 720 without forming on the surface 712 of the shallow trench isolation (STI) structures 708. In one example, the deposition process may be a epitaxial process, a plasma enhanced chemical vapor deposition (CVD), a flowable chemical vapor deposition (CVD), a high density plasma (HDP) chemical vapor deposition (CVD) process, atomic layer deposition (ALD), cyclical layer deposition (CLD), physical vapor deposition (PVD), or the like as needed. In one embodiment, the insulating material is formed by a flowable or plasma enhanced chemical vapor deposition (CVD).

Different materials for forming the material layer 724 and lower portion 710 of the fin structure 705 may have different adhesions and absorbability on the interface 720, i.e., a material adhered on a particular surface comprised of a first type of material disposed on a substrate may not be successfully adhered on a second material formed on the same substrate. As such, by careful selection of a material that may have high adhesion to the lower portion 710, the fin structure 705 with two different types of materials may be formed by utilizing of a selective deposition process. In one example, the material selected to form the material layer 724 may have similar lattice constant to the material of the lower portion 710 of the fin structure 705. In one example, a Ge or SiGe layer 724 may be formed in the openings 722 on the lower portion 710 made by a crystalline silicon layer to complete the fin structure 705.

Since the Ge material from the material layer 724 may have a similar lattice constant to the crystalline silicon material forming the lower portion 710, the material layer 724 may be easily grown on and absorbed on the lower portion 710 with the crystalline silicon material. In contrast, Ge material from the material layer 724 generally has a lattice constant very different from that of the insulating material selected to fabricate the shallow trench isolation (STI) structures 708. As such, the probability of the Ge materials becoming adhered onto the shallow trench isolation (STI) structures 708 with the insulating material for growth is very slim. By utilizing the material property difference, a selective deposition/growth of Ge material to form the material layer 724 may be enabled to predominately form on the interface 720 of the exposed lower portion 710 to form the fin structure 705 with composite materials.

In some examples, the material layer 724 selected to be grown in the openings 722 exposing the lower portion 710 may also be the same material as the lower portion 710 so as to re-form the fin structure 705 having an uniform material throughout the fin structure 705. The reformed fin structures 705 have an uniform height 730, so that mismatched heights resulting from the microloading effect may be eliminated.

Thus, methods for forming structures with desired materials, profile and dimensions for three dimensional (3D) stacking of fin field effect transistor (FinFET) for semiconductor chips are provided. The methods utilize an ion implantation process to ion ions to the fin structure forming a natural etching stop layer to promote etching selectivity. An etching process is utilized along with a selective deposition process to selectively remove areas with mismatched profiles and replaced with a different material or the same material but with uniform desired profiles. As such, a fin structure with uniform profile having the same material or with composite material is then obtained.

While the foregoing is directed to embodiments of the present invention, other and further embodiments of the invention may be devised without departing from the basic scope thereof, and the scope thereof is determined by the claims that follow.

1. A method for forming a structure on a substrate, the method comprising:
performing an ion implantation process on a substrate having a plurality of structures formed thereon;
forming an ion treated region in the structure at an interface between the ion treated region and an untreated region in the structure defining an etch stop layer; and
performing a remote plasma etching process to etch the treated region from the substrate to exposed the untreated region.

2. The method of claim 1, further comprising:
performing a selective deposition process to form a material layer on the untreated region in the structure.

3. The method of claim 1, wherein performing the remote plasma etching process further comprises:
forming a remote plasma from a gas mixture including a hydrogen containing gas.

4. The method of claim 3, wherein the hydrogen containing gas is selected from a group consisting of H₂, H₂O, H₂O₂ and NH₃.

5. The method of claim 1, wherein forming the ion treated region further comprises:
performing an directional ion implantation process to provide ions to the structure with an incident angle between about 0 degrees and about 60 degrees.

6. The method of claim 1, wherein forming the ion treated region further comprises:
supplying a gas mixture including an inert gas during the ion implantation process.

7. The method of claim 6, wherein forming the ion treated region further comprises:
forming an amorphous film structure in the treated region in response to a change in the lattice structure of the structure caused by atoms from the inert gas.

8. The method of claim 1, performing the ion implantation process on the substrate further comprises:
supplying a gas mixture including a doping gas during the ion implantation process.

9. The method of claim 8, wherein the doping gas mixture provides a dopant doping into the treated region but substantially no dopants into the untreated region in the structure.

10. The method of claim 7, wherein the treated region forms an amorphous silicon material.

11. The method of claim 9, wherein the treated region forms a n-type doped region or a p-type doped region.

12. The method of claim 1, wherein the treated region and the untreated region have different etching rate, providing an etching selectivity during the etching process.

13. The method of claim 2, wherein the material layer is a Ge containing material or a silicon containing material.

14. The method of claim 2, wherein the selective deposition process is an epitaxial deposition process, an atomic deposition process or a chemical vapor deposition process.

15. The method of claim 6, wherein the inert gas is Ar gas or Ne gas.

16. A method for forming a structure on a substrate, the method comprising:
forming an etching stop layer in a structure disposed on a substrate by an ion implantation process;
performing a remote plasma etching process to etch the structure until reaching the etching stop layer, defining openings exposing of the etching stop layer of the structure; and
performing a selective deposition process to form a material layer in the openings and on the etching stop layer.

17. The method of claim 16, wherein the etching stop layer is defined between an ion treated region and an ion untreated region in the structure.

18. The method of claim 17, wherein the ion implantation process damage lattice structure of the ion treated region, forming an amorphous structure in the treated region.

19. The method of claim 18, wherein the ion treated region has an etching rate different from the untreated region of the structure.

20. A method for forming a structure on a substrate, the method comprising:
performing a directional ion plasma process on a structure formed on a substrate to form an etching stop layer in the structure, wherein the structure is formed on the substrate between shallow trench isolation structures fabricated from insulating materials;
performing a remote plasma etching process including hydrogen radicals to etch a portion of the structure until reaching the etching stop layer exposing an underlying portion of the structure; and
performing a selective deposition process to form a material layer on the underlying portion of the structure.
